(19) United States
(12) Patent Application Publication
(10) Pub. No.: US 2024/0421050 A1
(43) Pub. Date: Dec. 19, 2024

(54) LEADFRAME AND SEMICONDUCTOR DEVICE

(71) Applicant: SHINKO ELECTRIC INDUSTRIES CO., LTD., Nagano (JP)

(72) Inventors: Etsuo UEMATSU, Nagano (JP); Hiromi UEHARA, Nagano (JP); Kesayuki SONEHARA, Nagano (JP); Akinobu HOJO, Nagano (JP)

(21) Appl. No.: 18/731,667

(22) Filed: Jun. 3, 2024

(30) Foreign Application Priority Data
Jun. 14, 2023 (JP) 2023-097782

(51) Int. Cl. H01L 23/495; H01L 23/00; H01L 25/065

(52) U.S. Cl. CPC H01L 23/49575; H01L 23/4951; H01L 23/49548; H01L 24/32; H01L 24/48; H01L 24/73; H01L 25/0657; H01L 2224/32145; H01L 2224/32245; H01L 2224/48132; H01L 2224/48175; H01L 2224/73265; H01L 2225/0651; H01L 2924/01028; H01L 2924/01029; H01L 2924/01046; H01L 2924/01079; H01L 2924/182

(57) ABSTRACT

A leadframe includes a die pad having a surface that includes a region for mounting a semiconductor chip, and a flat film and a roughened film on the surface of the die pad. In a plan view, the flat film is along and outside the outer edge of the region and the roughened film is inside and outside the flat film. The roughened film includes a roughened plating film and a plating film on the roughened plating film. The plating film follows the shape of the roughened plating film to have a roughened surface. The flat film has a flatter surface than the roughened film, and includes a first metal film formed of the same material as the roughened plating film and a second metal film on the first metal film. The second metal film is an alloy film including metals of the roughened plating film and the plating film.

### CROSS-REFERENCE TO RELATED APPLICATION

This application is based upon and claims priority to Japanese Patent Application No. 2023-097782, filed on Jun. 14, 2023, the entire contents of which are incorporated herein by reference.

### FIELD

A certain aspect of the embodiments discussed herein is related to leadframes and semiconductor devices.

### BACKGROUND

A semiconductor device including a leadframe and a semiconductor chip mounted on the leadframe and encapsulated with resin is known. Such a semiconductor device repeats expansion and contraction because of heat generated during operation. Therefore, a surface of the leadframe is roughened to increase the adhesion between the leadframe and the resin.

When the surface of the leadframe is roughened, a solvent component contained in an adhesive used to fix the semiconductor chip onto the leadframe is likely to wet and spread over the surface of the leadframe. The solvent component may reduce the adhesion between the leadframe and the resin. Therefore, various techniques for preventing the wetting and spreading of the solvent component have been studied (see, for example, Japanese Patent No. 5408457).

### SUMMARY

According to an aspect, a leadframe includes a die pad having a surface that includes a region for mounting a semiconductor chip, and a flat film and a roughened film on the surface of the die pad. In a plan view, the flat film is along and outside the outer edge of the region and the roughened film is inside and outside the flat film. The roughened film includes a roughened plating film and a plating film on the roughened plating film. The plating film follows the shape of the roughened plating film to have a roughened surface. The flat film has a flatter surface than the roughened film, and includes a first metal film formed of the same material as the roughened plating film and a second metal film on the first metal film. The second metal film is an alloy film including metals of the roughened plating film and the plating film.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a top view of the entirety of a leadframe according to a first embodiment;

FIGS. 2A and 2B are diagrams illustrating one of individual piece regions and its vicinity of the leadframe according to the first embodiment;

FIG. 3 is a top view illustrating a variation of the shape of a flat film;

FIG. 4 is a top view illustrating another variation of the shape of the flat film;

FIG. 5 is a top view illustrating yet another variation of the shape of the flat film;

FIGS. 6A and 6B are diagrams illustrating a method of calculating an S ratio;

FIGS. 7A and 7B are sectional views illustrating example configurations of the flat film and a roughened film;

FIG. 8 is a schematic diagram illustrating how the wetting and spreading of a solvent component is prevented;

FIGS. 9A through 9D are diagrams illustrating a process of manufacturing a leadframe according to the first embodiment;

FIGS. 10A through 10F are diagrams illustrating experimental results of the wetting and spreading of the solvent component;

FIG. 11 presents photographs taken with an atomic force microscope;

FIG. 12 presents surface appearance photographs taken with a scanning electron microscope;

FIG. 13 illustrates EDS analysis results;

FIG. 14 is a sectional view schematically illustrating a laser-irradiated part according to a comparative example;

FIG. 15 is a sectional view of a semiconductor device according to a second embodiment; and

FIGS. 16A through 16D are diagrams illustrating a method of manufacturing a semiconductor device according to the second embodiment.

### DESCRIPTION OF EMBODIMENTS

The related-art techniques, however, may be unable to sufficiently prevent the wetting and spreading of the solvent component. Therefore, there is a demand for further improvement in the technique of preventing the wetting and spreading of the solvent component.

According to an embodiment, a leadframe that is improved in preventing the wetting and spreading of a solvent component is provided.

Embodiments of the invention are explained below with reference to the accompanying drawings. In the following, the same elements are referred to using the same reference numerals, and duplicate description thereof may be omitted.

### [A] FIRST EMBODIMENT

[Leadframe structure]

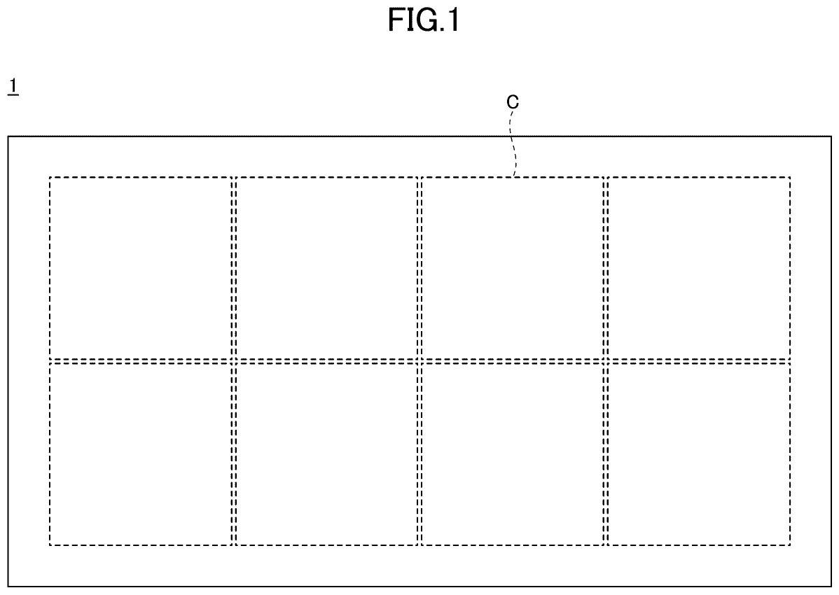

FIG. 1 is a plan view illustrating the entirety of a leadframe 1 according to a first embodiment. Referring to FIG. 1, the leadframe 1 includes multiple individual piece regions C. The individual piece regions C are one-dimensionally or two-dimensionally arranged, being spaced apart from each other. The individual piece regions C are ultimately cut into individual pieces, each becoming part of a semiconductor device. The number of the individual piece regions C may be determined as desired according to required specifications. While depicted as having a rectangular shape in FIG. 1 for simplification, the individual piece regions C do not have to have a rectangular shape and may have a more complicated shape that matches the shape of a semiconductor device. Examples of materials that may be used for the leadframe 1 include copper (Cu), copper alloys, and Alloy 42. The thickness of the leadframe 1 may be, for example, 100 μm or more and 200 μm or less.

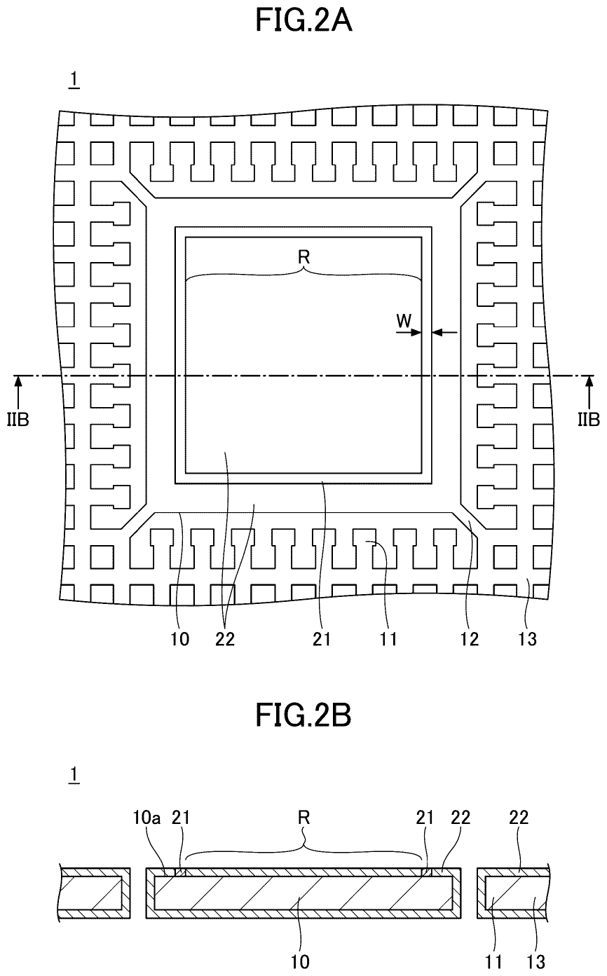

FIGS. 2A and 2B are diagrams illustrating one of the individual piece regions C and its vicinity of the leadframe 1 according to the first embodiment. FIG. 2A is a top view and FIG. 2B is a sectional view taken along the line IIB-IIB of FIG. 2A.

Referring to FIGS. 2A and 2B, a die pad 10 is placed in the center of the individual piece region C. The die pad 10 has a rectangular shape in a plan view, for example. The length of one side of the die pad 10 is, for example, approximately 5 mm to approximately 15 mm. Outward extending leads 11 are provided outside the die pad 10, being separated from the die pad 10. The leads 11 extend in directions perpendicular to the outer sides of the die pad 10 in a top view, for example.

Support bars 12 extend outward from the four corners of the die pad 10. A frame 13 having a frame shape is provided outside the die pad 10, being separated from the die pad 10. The leads 11 and the support bars 12 are supported by being connected to the frame 13. That is, the die pad 10 is supported by being connected to the frame 13 by the support bars 12.

An upper surface 10a of the die pad 10 includes a mounting region R for mounting a semiconductor chip (a region where a semiconductor chip is to be mounted). The mounting region R has a rectangular shape whose one side is approximately 4 mm to approximately 13 mm in length in a plan view, for example. On the upper surface 10a of the die pad 10, a flat film 21 is provided along, for example, extends along, the outer edge of the mounting region R outside the mounting region R in a plan view. The flat film 21 is provided in a frame or ring shape, for example. According to the illustrated example, the flat film 21 is provided in a rectangular frame shape along the outer edge of the mounting region R. In other words, the mounting region R is a region enclosed by the flat film 21. The width W of the flat film 21 may be, for example, 0.1 mm or more and 2 mm or less.

The flat film 21 does not have to be provided in a frame or ring shape, depending on the shape of a leadframe. The flat film 21 is not limited to a frame or ring shape, and may also be, for example, U-shaped, two parallel straight lines, a single straight line, or the like. Specific examples of the shape of the flat film 21 are described below.

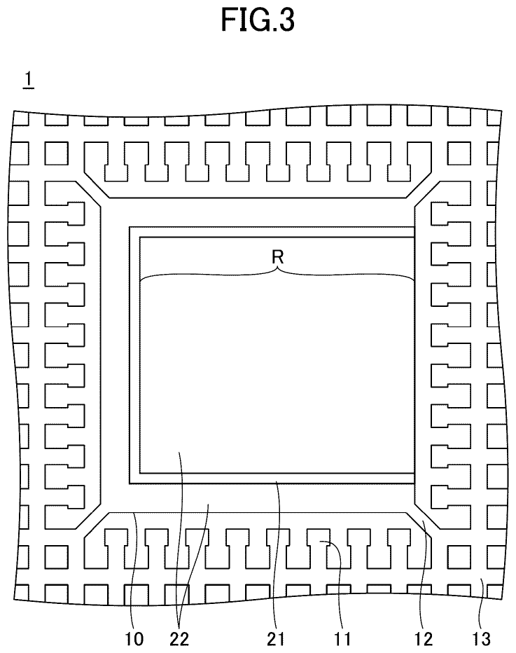

FIG. 3 is a top view illustrating a variation of the shape of the flat film 21. Referring to FIG. 3, the flat film 21, which is substantially U-shaped, is formed along the perimeter (outline) of the rectangular die pad 10 with the start end and the terminal end of the flat film 21 being in contact with one side (the right side in FIG. 3) of the rectangular die pad 10.

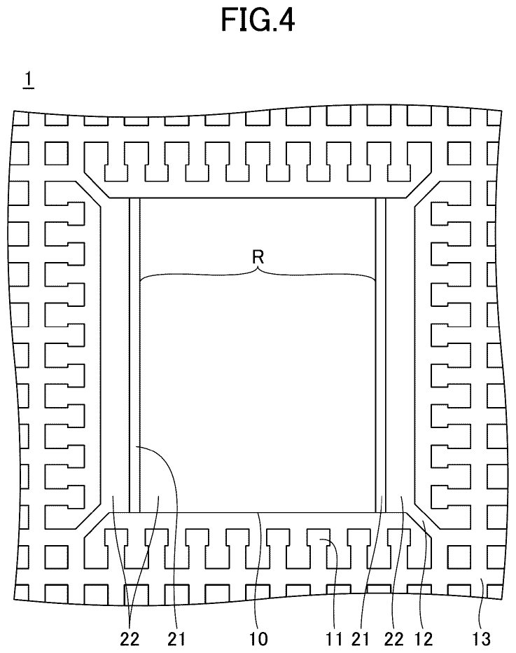

FIG. 4 is a top view illustrating another variation of the shape of the flat film 21. Referring to FIG. 4, the flat film 21, which has the shape of two parallel straight lines, is formed along two opposite sides (the right side and the left side in FIG. 4) of the rectangular die pad 10 with the start end and the terminal end of the flat film 21 having the shape of two parallel straight lines being in contact with two other opposite sides (the upper side and the lower side in FIG. 4) of the rectangular die pad 10.

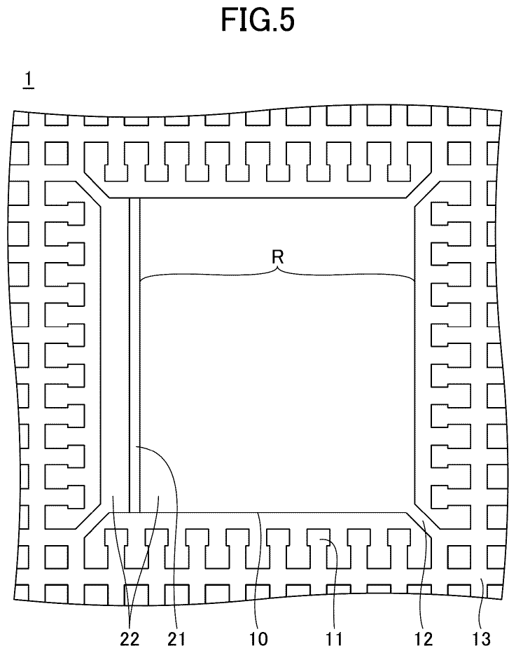

FIG. 5 is a top view illustrating yet another variation of the shape of the flat film 21. Referring to FIG. 5, the flat film 21, which has the shape of a single straight line, is formed along one side (the left side in FIG. 5) of the rectangular die pad 10 with the start end and the terminal end of the flat film 21 having the shape of a single straight line being in contact with two opposite sides (the upper side and the lower side in FIG. 5) of the rectangular die pad 10 contacting the one side (the left side in FIG. 5).

On the upper surface 10a of the die pad 10, a roughened film 22 is provided inside (or within) and outside of the flat film 21, for example, relative to the center of the upper surface 10a, in a plan view. In the case of FIG. 4, the inside of the flat film 21 is the region sandwiched between the two straight lines of the flat film 21 in a plan view, and the outside of the flat film 21 is the region sandwiched between the two straight lines of the flat film 21 and the sides of the die pad 10 along the two straight lines. In the case of FIG. 5, the inside of the flat film 21 is one of the two regions into which the upper surface 10a of the die pad 10 is divided by the flat film 21 in a plan view, and the outside of the flat film 21 is the other of the two regions into which the upper surface 10a of the die pad 10 is divided by the flat film 21 in a plan view. The roughened film 22 may be provided on the lower surface and the side surface as well of the die pad 10, in addition to the upper surface 10a of the die pad 10. The roughened film 22 may also be provided on one or more of the upper surface, the side surface, and the lower surface of one or more of the leads 11, the support bars 12, and the frame 13.

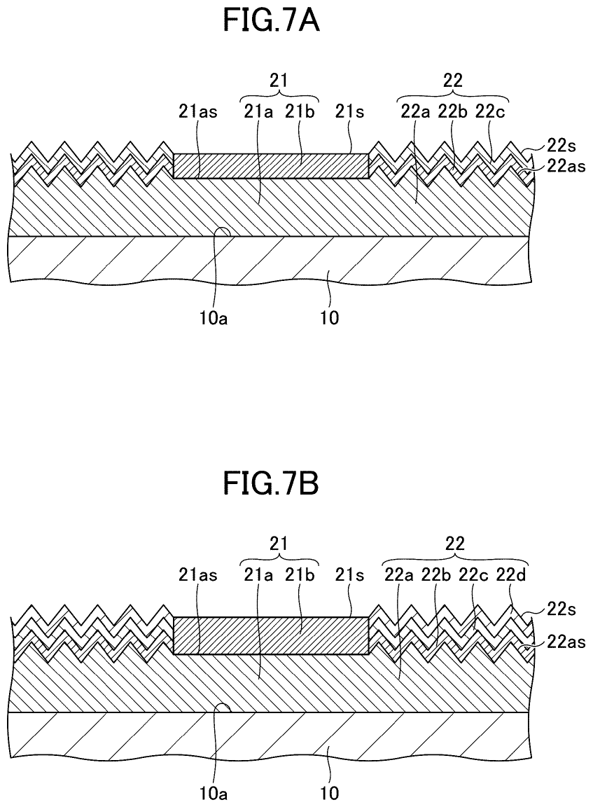

A surface 21s of the flat film 21 is flatter than a surface 22s of the roughened film 22 (see, for example, FIGS. 7A and 7B). Specifically, the arithmetic mean height Sa of the flat film 21 is smaller than the arithmetic mean height Sa of the roughened film 22. The arithmetic mean height Sa of the flat film 21 is, for example, 20 nm or more and 50 nm or less. The arithmetic mean height Sa of the roughened film 22 is, for example, 80 nm or more and 120 nm or less.

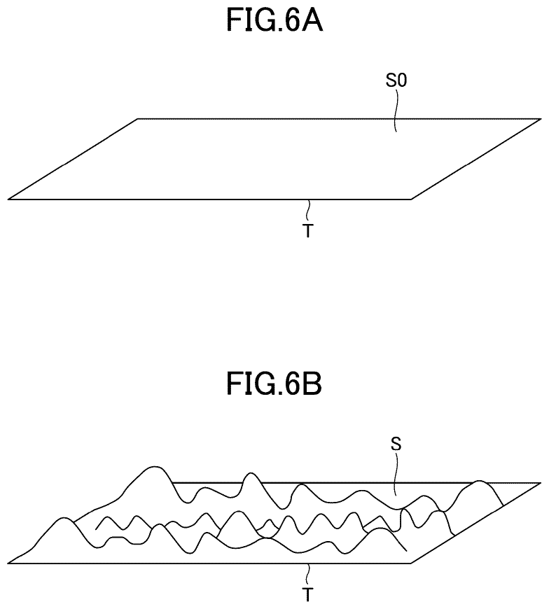

The S ratio of the flat film 21 is smaller than the S ratio of the roughened film 22. The S ratio of the flat film 21 is, for example, 1.01 or more and 1.10 or less. The S ratio of the roughened film 22 is, for example, more than 1.10 and 2.20 or less. The S ratio is the ratio of S to S0, where S0 is the area of a region T in a plan view as illustrated in FIG. 6A while S is the real surface area of the region T as illustrated in FIG. 6B. That is, the S ratio is expressed as “S/S0.”

The flat film 21 is higher in glossiness than the roughened film 22. The glossiness of the flat film 21 is, for example, 1.5 or more and 1.9 or less. The glossiness of the roughened film 22 is, for example, 0.4 or more and 0.8 or less. The glossiness of the flat film 21 is, for example, at least twice and at most three times the glossiness of the roughened film 22. The glossiness may be measured using, for example, VSR400 manufactured by NIPPON DENSHOKU INDUSTRIES CO., LTD.

With reference to the upper surface 10a of the die pad 10, the maximum height of the flat film 21 is smaller than the maximum height of the roughened film 22. With reference to the upper surface 10a of the die pad 10, the difference between the maximum height of the flat film 21 and the maximum height of the roughened film 22 is less than 1 μm. Thus, there is no substantial step (difference in level) between the upper surface (surface 21s) of the flat film 21 and the upper surface (surface 22s) of the roughened film 22.

FIGS. 7A and 7B are sectional views of part of the die pad 10, illustrating example configurations of the flat film 21 and the roughened film 22. Referring to FIG. 7A, the flat film 21 includes a first metal film 21a and a second metal film 21b stacked on the first metal film 21a. The roughened film 22 includes a roughened plating film 22a having a roughened surface 22as, and plating films 22b and 22C stacked in layers on the roughened plating film 22a. The plating films 22b and 22c are sufficiently thinner than the roughened plating film 22a, and therefore follow the shape of the roughened plating film 22a to have respective roughened surfaces. An upper surface 21as of the first metal film 21a is flatter than the upper surface (roughened surface 22as) of the roughened plating film 22a.

The roughened plating film 22a may be formed of, for example, Cu or nickel (Ni). The plating film 22b may be formed of, for example, palladium (Pd). The plating film 22c may be formed of, for example, gold (Au). The first metal film 21a is formed of the same metal as the roughened plating film 22a. For example, when the roughened plating film 22a is Cu, the first metal film 21a is formed of Cu. When the roughened plating film 22a is Ni, the first metal film 21a is formed of Ni.

The second metal film 21b is an alloy film of the metal forming the roughened plating film 22a and the metals forming the plating films 22b and 22c. For example, when the roughened plating film 22a is Cu, the plating film 22b is Pd, and the plating film 22c is Au, the second metal film 21b is an alloy film of Cu, Pd, and Au. When the roughened plating film 22a is Ni, the plating film 22b is Pd, and the plating film 22c is Au, the second metal film 21b is an alloy film of Ni, Pd, and Au.

Referring to FIG. 7B, the roughened film 22 may also be configured to include the roughened plating film 22a and the plating films 22b and 22c and a plating film 22d that are stacked in layers on the roughened plating film 22a. The plating films 22b, 22c, and 22d are sufficiently thinner than the roughened plating film 22a, and therefore follow the shape of the roughened plating film 22a to have respective roughened surfaces.

The roughened plating film 22a may be formed of, for example, Cu. The plating film 22b may be formed of, for example, Ni. The plating film 22c may be formed of, for example, Pd. The plating film 22d may be formed of, for example, Au. The first metal film 21a is formed of the same metal as the roughened plating film 22a. For example, when the roughened plating film 22a is Cu, the first metal film 21a is formed of Cu.

The second metal film 21b is an alloy film of the metal forming the roughened plating film 22a and the metals forming the plating films 22b, 22c, and 22d. For example, when the roughened plating film 22a is Cu, the plating film 22b is Ni, the plating film 22c is Pd, and the plating film 22d is Au, the second metal film 21b is an alloy film of Cu, Ni, Pd, and Au.

As described in detail below, in the case of manufacturing a semiconductor device using the leadframe 1, an adhesive such as Ag paste (die attach paste) is applied on the mounting region R and a semiconductor chip is mounted on the adhesive. The semiconductor chip and leads are encapsulated with resin that contacts the roughened film 22 positioned outside the flat film 21.

If the flat film 21 is not formed and the roughened film 22 is continuously formed from the inside to the outside of the mounting region R, a solvent component contained in the adhesive is likely to wet and spread over the surface 22s of the roughened film 22 because of capillary action. The solvent component wetting and spreading over the roughened film 22 would reduce the adhesion between the resin and the roughened film 22.

Therefore, according to the leadframe 1, the flat film 21 is provided along the outer edge of the mounting region R in a plan view on the upper surface 10a of the die pad 10. Accordingly, the solvent component is prevented from wetting and spreading over the roughened film 22 positioned outside the flat film 21 through capillary action. Therefore, reduction in the adhesion due to the solvent component contained in the adhesive is prevented, so that good adhesion between the resin and the roughened film 22 positioned outside the flat film 21 can be obtained.

FIG. 8 is a schematic diagram illustrating how the wetting and spreading of a solvent component is prevented. Referring to FIG. 8, Ag paste 151 is applied as an adhesive on a circular area in the mounting region R. The Ag paste 151 is applied at a distance from the flat film 21. The flatness of the roughened film 22 of the mounting region R is lower than the flatness of the flat film 21. Therefore, a solvent component 152 contained in the Ag paste 151 is wetting and spreading circularly around the Ag paste 151 within the mounting region R. On the other hand, the solvent component 152 does not cross the boundary between the mounting region R and the flat film 21 to remain inside the mounting region R. Thus, by providing the flat film 21, the wetting and spreading of the solvent component 152 is prevented.

As another method of preventing the wetting and spreading of a solvent component contained in an adhesive, pressing a roughened film with a die to form a depression with reduced roughness may be possible instead of forming a flat film. According to this method, the part of the roughened film pressed by the die is crushed, so that the flatness of the crushed part becomes higher than the flatness of an uncrushed part. The depth of the depression is, for example, approximately 1 μm to approximately 2 μm. Such processing may be referred to as coining. According to coining, because a material forming the die pad tries to extend to a surrounding area, there is the adverse effect that the flatness of the die pad is reduced. As described below, according to an embodiment, the flat film is formed by laser processing. In the case of forming a flat film by laser processing, the material of the die pad neither stretches or shrinks. Therefore, the flatness of the die pad is not impaired.

Furthermore, coining is applicable to leadframes whose design allows easy pressing, such as those used for packages such as small outline packages (SOPs) and quad flat packages (QFPs). Coining, however, is difficult to apply to leadframes formed by etching, such as those used for quad flat non-leaded (QFN) packages. In contrast, forming a flat film by laser processing according to an embodiment is applicable to both types of leadframes.

Furthermore, it may be possible to apply a hydrophobic organic agent to part of the roughened surface to prevent the wetting and spreading of the solvent component contained in the adhesive. Conversely, however, such an organic agent may reduce the adhesion between the leadframe and the resin. Furthermore, use of an organic agent is likely to lead directly to an increase in costs. Moreover, it may take a lot of effort to apply a desired amount of an organic agent to a desired position. In addition, an organic agent may be heated to change in quality. In particular, in the case of mounting multiple semiconductor chips on the single die pad 10, heating may be performed multiple times. In this case, the organic agent may be likely to change in quality.

Furthermore, the roughened film 22 and the flat film 21 are different in glossiness. Therefore, the flat film 21 can be easily identified visually or using an optical microscope. In contrast, when such an amount of an organic agent as not to reduce the adhesion is applied on the roughened film (roughened surface), the difference in glossiness between the roughened film and the organic agent is limited. Therefore, it is difficult to determine, visually or using an optical microscope, whether the organic agent is applied.

### [Method of Manufacturing Leadframe]

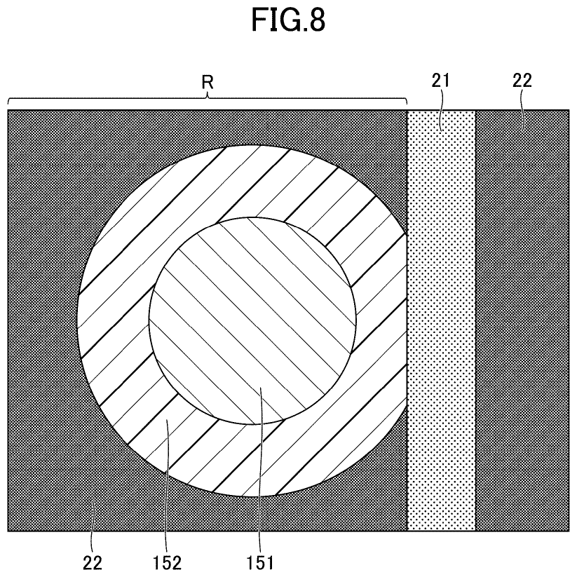

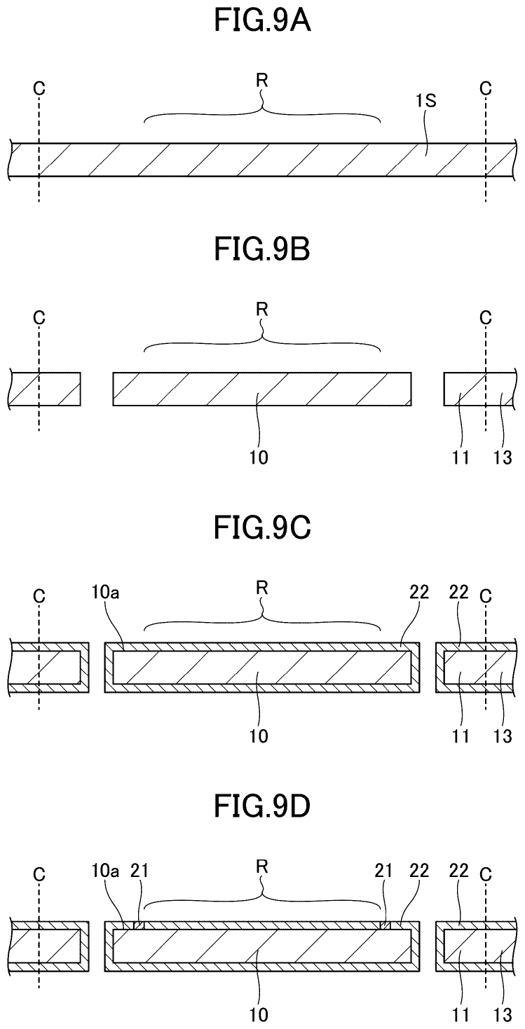

Next, a method of manufacturing a leadframe according to the first embodiment is described. FIGS. 9A through 9D are diagrams illustrating a process of manufacturing a leadframe according to the first embodiment, each being a sectional view of one of the individual piece regions and its vicinity of a leadframe. The sections illustrated in FIGS. 9A through 9D correspond to the position of the line IIB-IIB of FIG. 2A.

Referring to FIG. 9A, first, a metal sheet 1S having a predetermined shape is prepared. The metal sheet 1S is eventually cut and divided into individual pieces each corresponding to one of the individual piece regions C (see FIG. 1). The mounting region R for mounting a semiconductor chip is defined in each of the individual piece regions C. Materials that may be used for the metal sheet 1S include Cu, Cu alloys, and Alloy 42. The thickness of the metal sheet 1S may be, for example, 100 μm or more and 200 μm or less. The S ratio of the surface of the metal sheet 1S may be, for example, approximately 1.00 to approximately 1.03 over the entirety of the surface.

Next, referring to FIG. 9B, wet etching is performed on the metal sheet 1S to form the die pad 10, the leads 11, the support bars 12, and the frame 13 that are shaped as illustrated in FIG. 2A. Specifically, for example, a resist film having openings is formed on the upper surface and the lower surface of the metal sheet 1S. The openings on the upper surface side of the metal sheet 1S and the openings on the lower surface side of the metal sheet 1S are positioned one over the other in a plan view. The metal sheet 1S exposed in the openings is removed, using the resist films as etching masks, to form the die pad 10, the leads 11, the support bars 12, and the frame 13 that are shaped as illustrated in FIG. 2A.

Next, referring to FIG. 9C, the roughened film 22 is formed inside and outside the mounting region R in a plan view on the upper surface 10a of the die pad 10. The roughened film 22 may be formed on the entirety of the die pad 10, the leads 11, the support bars 12, and the frame 13. To form the roughened film 22, first, the roughened plating film 22a is formed by roughened Ni plating. Specifically, an acid plating bath containing a halogen (for example, a Ni halide) is used during Ni plating by cathode electrolysis. Using an acid plating bath containing a halogen results in Ni with large crystal grains, compared with the case of using an acid plating bath containing no halogen. According to this method, the S ratio of the surface (roughened surface 22as) of the roughened plating film 22a is, for example, 1.20 or more and 1.80 or less. Furthermore, the arithmetic mean height Sa of the roughened plating film 22a is, for example, 80 nm or more and 120 nm or less.

An example of a plating bath composition and plating conditions is shown below. By controlling current density and plating time with respect to this plating bath, the roughened plating film 22a having a predetermined thickness and surface roughness can be obtained.

### Nickel Chloride Plating Bath:

nickel chloride 75 g/L
sodium thiocyanate 15 g/L
ammonium chloride 30 g/L
pH: approximately 4.5 to approximately 5.5
Bath temperature: room temperature (approximately 25° C.)
Cathode current density: approximately 1 A/cm² to approximately 3 A/cm².

Thereafter, for example, Pd and Au are successively stacked in layers as the plating film 22b and the plating film 22c, respectively, by electroplating or the like. As a result, the roughened film 22 is formed. The thickness of the plating film 22b may be, for example, approximately 0.005 μm. The thickness of the plating film 22c may be, for example, approximately 0.0005 μm. The plating films 22b and 22c are extremely thin. Therefore, the plating films 22b and 22c are formed along the roughened surface 22as of the roughened plating film 22a. As a result, the surface roughness of the roughened film 22 is equal to the surface roughness of the roughened plating film 22a.

The roughened plating film 22a may be formed by roughened Cu plating. For example, coarse crystals in a high current density region are locally deposited when performing plating by cathode electrolysis on the surfaces of the die pad 10, the leads 11, the support bars 12, and the frame 13, using a copper sulfate-based plating solution. As a result, the roughened plating film 22a of Cu is formed. According to this method, the S ratio of the surface (roughened surface 22as) of the roughened plating film 22a is, for example, 1.20 or more and 2.20 or less. Furthermore, the arithmetic mean height Sa of the roughened plating film 22a is, for example, 80 nm or more and 120 nm or less.

Thereafter, as described above, for example, Pd and Au are successively stacked in layers as the plating film 22b and the plating film 22c, respectively. As a result, the roughened film 22 is formed. Ni, Pd, and Au may be successively stacked in layers as the plating film 22b, the plating film 22c, and the plating film 22d, respectively, after forming the roughened plating film 22a of Cu. In either case, the surface roughness of the roughened film 22 is equal to the surface roughness of the roughened plating film 22a.

Next, referring to FIG. 9D, the flat film 21 is formed. The composition of the flat film 21 is as described above. The S ratio of the flat film 21 is, for example, 1.01 or more and 1.10 or less. The arithmetic mean height Sa of the flat film 21 is, for example, 20 nm or more and 50 nm or less. The flat film 21 may be formed along the outer edge of the mounting region R by radiating laser light onto part of the roughened film 22 positioned outside the mounting region R. For example, a green laser having a wavelength of approximately 532 nm and a spot size of approximately 2 μm may be employed to radiate laser light. Using the green laser, which is a short-wavelength laser, makes it possible to form the flat film 21 with a small arithmetic mean height Sa and a small S ratio. The arithmetic mean height Sa and the S ratio of the flat film 21, however, may vary according to the intensity of radiated laser light. Therefore, it is preferable to determine, through experiments or simulations in advance, intensity with which a desired arithmetic mean height Sa and S ratio are obtained and to radiate laser light with the determined intensity.

In this manner, the leadframe 1 according to the first embodiment can be manufactured.

Here, experiments for confirming effects according to the embodiment and their results are described.

### [Experiment 1]

First, a roughened film having a Ni layer, a Pd layer, and a Au layer in this order was formed on a surface of a copper sheet, and laser light was radiated onto the roughened film under Conditions A to form a rectilinear laser-irradiated part A of approximately 0.1 mm in width. Multiple copper sheets on which the laser-irradiated part A was formed were prepared. Next, a copper sheet having the same specifications as described above was prepared, and laser light was radiated onto the upper surface of the copper sheet under Conditions B to form a rectilinear laser-irradiated part B of approximately 0.1 mm in width. Multiple copper sheets on which the laser-irradiated part B was formed were prepared. A green laser having a wavelength of approximately 532 nm and a spot size of approximately 2 μm was employed to radiate laser light. Conditions A and B only differ in the intensity of irradiated laser light and are equal in the other conditions. The intensity of laser light radiated under Conditions B was approximately twice the intensity of laser light radiated under Conditions A.

Next, three types of Ag paste that are different in specifications, namely, Ag paste 1, Ag paste 2, and Ag paste 3, were prepared. One of the Ag pastes 1 through 3 was applied onto each of the copper sheets on which the laser-irradiated part A or the laser-irradiated part B was formed, and it was evaluated whether the wetting and spreading of a solvent component in the Ag paste stopped at the laser-irradiated part A or the laser-irradiated part B. The evaluation was performed at three points of time, namely, immediately after application of the Ag paste, after being left for 24 hours since the application, and after being left for 24 hours since the application and then being heated at 180° C. for one hour.

### [Results]

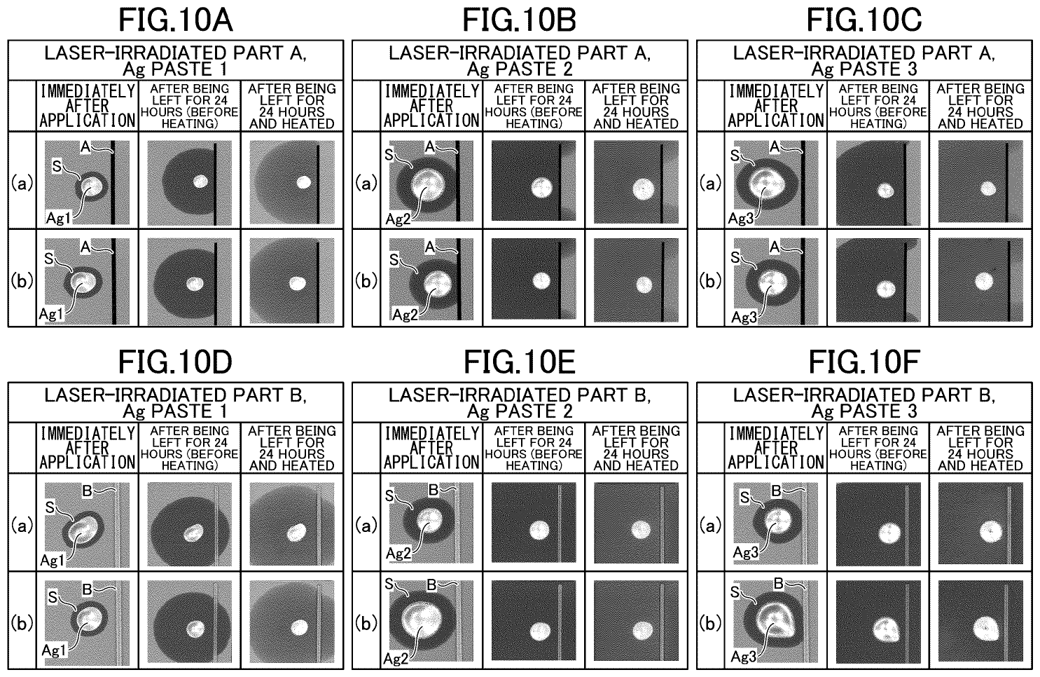

FIGS. 10A through 10F are diagrams illustrating experimental results of the wetting and spreading of a solvent component. In FIGS. 10A through 10F, “IMMEDIATELY AFTER APPLICATION” is a result immediately after application of the Ag paste. Furthermore, “AFTER BEING LEFT FOR 24 HOURS (BEFORE HEATING)” is a result after being left for 24 hours since the application. Furthermore, “AFTER BEING LEFT FOR 24 HOURS AND HEATED” is a result after being left for 24 hours since the application and then being heated for at 180° C. for one hour. Furthermore, (a) and (b) indicate different samples. Furthermore, in FIGS. 10A through 10F, “A” indicates the laser-irradiated part A, “B” indicates the laser-irradiated part B, “Ag1” through “Ag3” indicate the Ag paste 1 through the Ag paste 3, and “S” indicates a solvent component.

As illustrated in FIGS. 10A through 10C, it was confirmed that the wetting and spreading of the solvent component S in the Ag pastes 1 through 3 can be prevented at any point of time, namely, any of “IMMEDIATELY AFTER APPLICATION,” “AFTER BEING LEFT FOR 24 HOURS (BEFORE HEATING),” and “AFTER BEING LEFT FOR 24 HOURS AND HEATED,” on the copper sheets on which the laser-irradiated part A is formed. It is observed that the solvent component S in the Ag paste runs around the upper end and the lower end of the laser-irradiated part A. It is believed that this is due to the rectilinear formation of the laser-irradiated part A and can be avoided by forming the laser-irradiated part A in a frame shape.

In contrast, as illustrated in FIGS. 10D through 10F, on the copper sheets on which the laser-irradiated part B is formed, the wetting and spreading of the solvent component S in the Ag pastes 1 through 3 is prevented “IMMEDIATELY AFTER APPLICATION,” while the wetting and spreading of the solvent component S in the Ag pastes 1 through 3 is not prevented neither “AFTER BEING LEFT FOR 24 HOURS (BEFORE HEATING)” nor “AFTER BEING LEFT FOR 24 HOURS AND HEATED.” It is observed that the solvent component S in the Ag pastes 1 through 3 tends to wet and spread through the laser-irradiated part B with passages of time and be heated to further wet and spread.

### [Experiment 2]

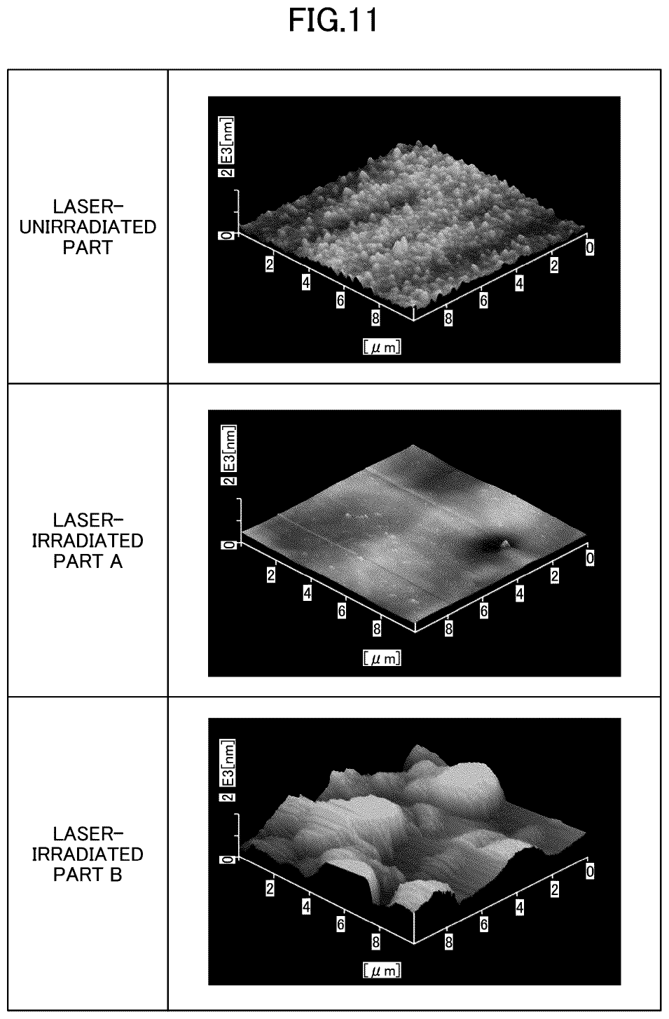

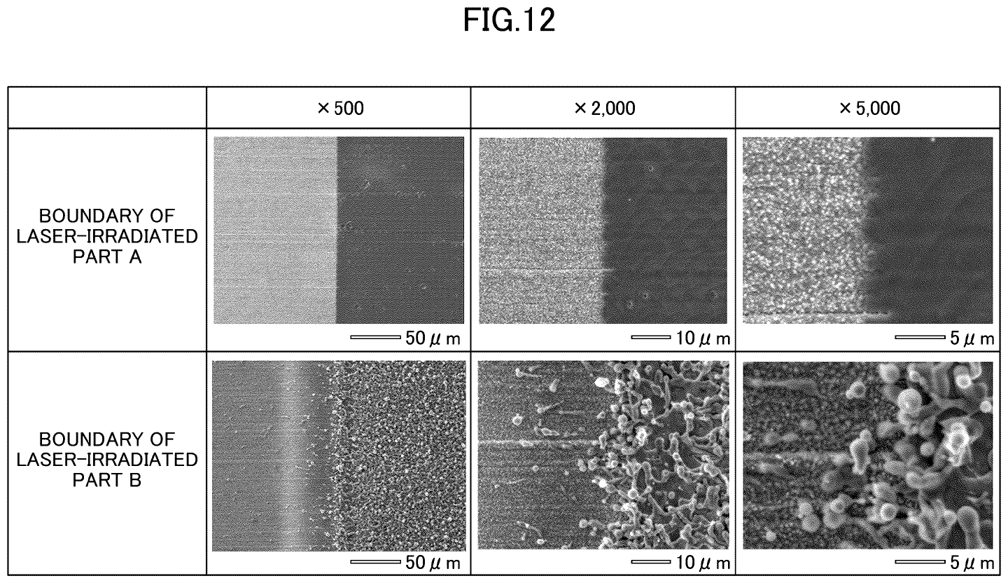

In Experiment 2, the difference in shape between the laser-irradiated part A and the laser-irradiated part B was studied. FIG. 11 presents photographs of a laser-unirradiated part, the laser-irradiated part A, and the laser-irradiated part B taken with an atomic force microscope. FIG. 12 presents surface appearance photographs of the boundary between the laser-unirradiated part and the laser-irradiated part A and the boundary between the laser-unirradiated part and the laser-irradiated part B taken with a scanning electron microscope at three magnifications. In each photograph, the left half is the laser-unirradiated part. The laser-unirradiated part is a surface of roughened plating not irradiated with laser light.

Furthermore, Table 1 presents the arithmetic mean heights Sa and the S ratios of the laser-unirradiated part, the laser-irradiated part A, and the laser-irradiated part B determined from the photographs of FIG. 11. Furthermore, Table 2 presents the results of measuring the glossiness of the laser-unirradiated part, the laser-irradiated part A, and the laser-irradiated part B with respect to five samples each. The glossiness was measured using VSR400 manufactured by NIPPON DENSHOKU INDUSTRIES CO., LTD.

TABLE 1

| | Sa [nm] | S ratio |
|---|---|---|
| Laser-unirradiated | 107.6 | 1.537 |
| part | | |
| Laser-irradiated | 32.79 | 1.037 |
| part A | | |
| Laser-irradiated | 35.13 | 1.753 |
| part B | | |

TABLE 2

| | Laser- | Laser- | Laser- |
|---|---|---|---|
| | unirradiated | irradiated | irradiated |
| | part | part A | part B |
| 1 | 0.617 | 1.737 | 0.869 |
| 2 | 0.624 | 1.736 | 0.859 |
| 3 | 0.632 | 1.659 | 0.857 |
| 4 | 0.638 | 1.595 | 0.87 |
| 5 | 0.64 | 1.768 | 0.859 |
| Maximum | 0.64 | 1.768 | 0.87 |
| Average | 0.63 | 1.699 | 0.863 |
| Minimum | 0.617 | 1.595 | 0.857 |

FIGS. 11 and 12 and Tables 1 and 2 indicate that the laser-irradiated part A is flat and has high glossiness. That is, a flat film is formed in the laser-irradiated part A. In contrast, the laser-irradiated part B is not flat and is a roughened surface in a different condition from the laser-unirradiated part. Therefore, the laser-irradiated part B has low glossiness and is visible as a brownish color. The laser-irradiated part A has glossiness approximately twice the glossiness of the laser-irradiated part B.

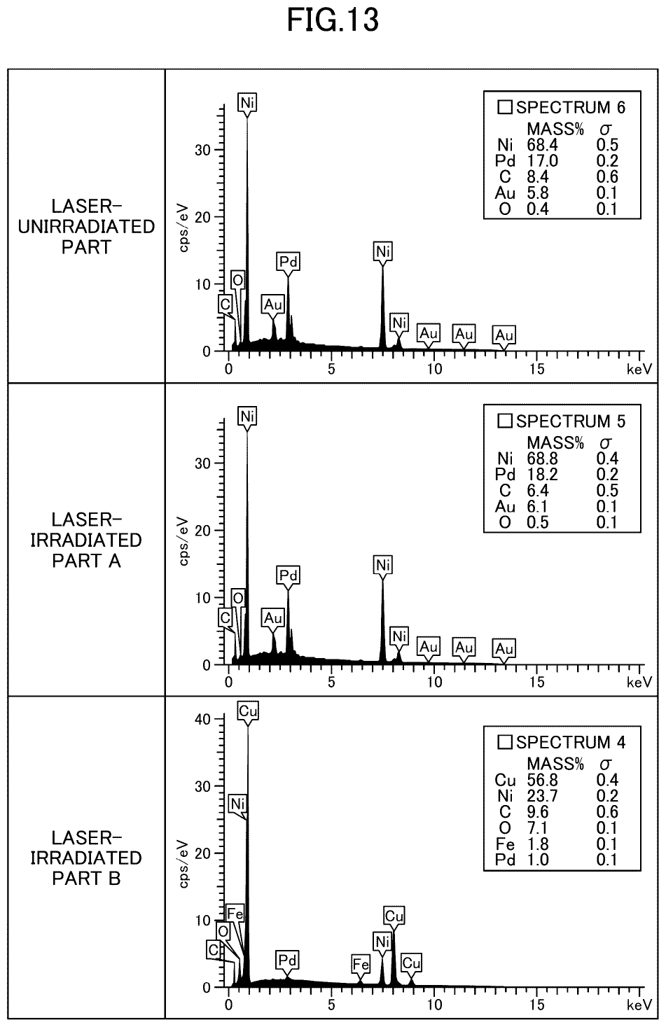

Next, an EDS analysis of the laser-unirradiated part, the laser-irradiated part A, and the laser-irradiated part B was conducted. The EDS analysis is an elemental analysis using energy dispersive X-ray spectroscopy. FIG. 13 illustrates the EDS analysis results. Referring to FIG. 13, a comparison between the laser-unirradiated part and the laser-irradiated part A shows that there are no substantial changes in the values of Ni (%), Au (%), and Pd (%). From this, it is considered that Au and Pd neither disappear nor decrease and have melted to generate an alloy film of Ni, Au, and Pd and recrystallize in the laser-irradiated part A.

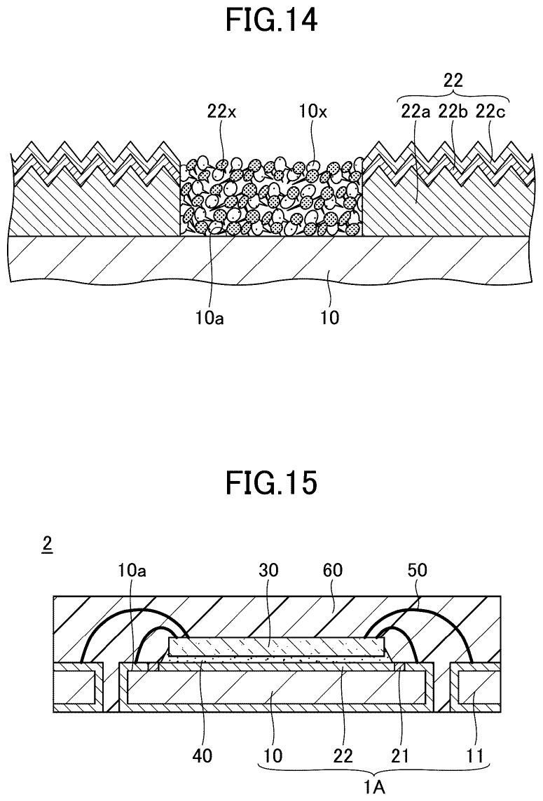

In contrast, a comparison between the laser-unirradiated part and the laser-irradiated part B in FIG. 13 shows that Au has disappeared and the value of Pd (%) has decreased in the laser-irradiated part B. Furthermore, a Cu component can be identified. From this, it is considered that in the laser-irradiated part B, as schematically illustrated in FIG. 14, Au and Pd have scattered and disappeared because of radiation of laser light and a granular part 22X in which Ni of the roughened film is scattered in particles and a granular part 10x in which Cu of the die pad 10 is scattered in particles are attached onto the die pad 10. Furthermore, it is considered that no alloy film of Ni, Au, and Pd is created in the laser-irradiated part B.

It has been found that, as illustrated above, the selection of appropriate intensity of laser light at the time of irradiating the roughened film with the laser light makes it possible to form an alloy film of the metals of the roughened film and causes the alloy film to be flat with high glossiness. It has also been found that this alloy film makes it possible to prevent the wetting and spreading of a solvent component in the Ag paste.

### [B] SECOND EMBODIMENT

Next, a second embodiment is described. The second embodiment relates to a semiconductor device manufactured using the leadframe 1 according to the first embodiment.

### [Structure of Semiconductor Device]

First, a structure of a semiconductor device is described. FIG. 15 is a sectional view of a semiconductor device 2 according to the second embodiment.

Referring to FIG. 15, the semiconductor device 2 includes a leadframe 1A, a semiconductor chip 30, an adhesive 40, metal wires 50 (bonding wires), and resin 60. The semiconductor device 2 is a QFN package.

The leadframe 1A is one of the individual pieces into which the leadframe 1 is divided, and is a part inside one of the individual piece regions C of the leadframe 1. The leadframe 1A includes the die pad 10 for mounting the semiconductor chip 30, the leads 11, and the support bars 12 (see FIG. 2A). Furthermore, the flat film 21 and the roughened film 22 as described in the first embodiment are provided on the upper surface 10a of the die pad 10, etc.

The semiconductor chip 30 is mounted face-up in the mounting region R (see FIGS. 2A and 2B) of the upper surface 10a of the die pad 10. For example, the semiconductor chip 30 may be mounted (by die bonding) in the mounting region R of the upper surface 10a of the die pad 10, using the adhesive 40 such as Ag paste. Electrode terminals formed on the upper surface of the semiconductor chip 30 are electrically connected (wire-bonded) to the upper surface 10a of the die pad 10 and the upper surfaces of the leads 11 via the metal wires 50 such as gold wires or copper wires.

The resin 60 is provided on the leadframe 1A. The resin 60 covers the upper surface and the side surface of the leadframe 1A. The lower surface of the leadframe 1A is exposed at the lower surface of the resin 60. The resin 60 contacts the roughened film 22 positioned outside the flat film 21 to encapsulate the semiconductor chip 30 and the metal wires 50. Part of the side surface of each lead 11 (the end face of the lead 11 cut from the frame 13) is exposed at the side surface of the resin 60. That is, the resin 60 encapsulates the semiconductor chip 30, etc., in such a manner as to expose part of the side surface of each lead 11. The flat film 21 and the roughened film 22 are not provided on the exposed part of the side surface of each lead 11. The exposed part of the side surface of each lead 11 serves as an external connection terminal. For example, so-called mold resin, namely, epoxy resin containing filler, may be used as the resin 60.

When moisture enters the resin (the interface between the resin and the leadframe) of a semiconductor device, the moisture in the resin rapidly expands and vaporizes to cause a crack or the like in the resin during reflow soldering or the like at the time of mounting the semiconductor device on a mounting substrate. Such a crack or the like destroys the semiconductor device.

According to the semiconductor device 2 of the second embodiment, the leadframe 1A is manufactured from the leadframe 1, so that the leadframe 1A includes the roughened film 22 that has good adhesion to the resin 60. Accordingly, it is possible to prevent the above-described entry of moisture and to prevent the destruction of the semiconductor device 2.

The flat film 21 formed by the radiation of laser light has a fine width, and does not significantly reduce the area of the roughened film 22. Therefore, the formation of the flat film 21 does not reduce the adhesion between the roughened film 22 and the resin 60.

### [Method of Manufacturing Semiconductor Device]

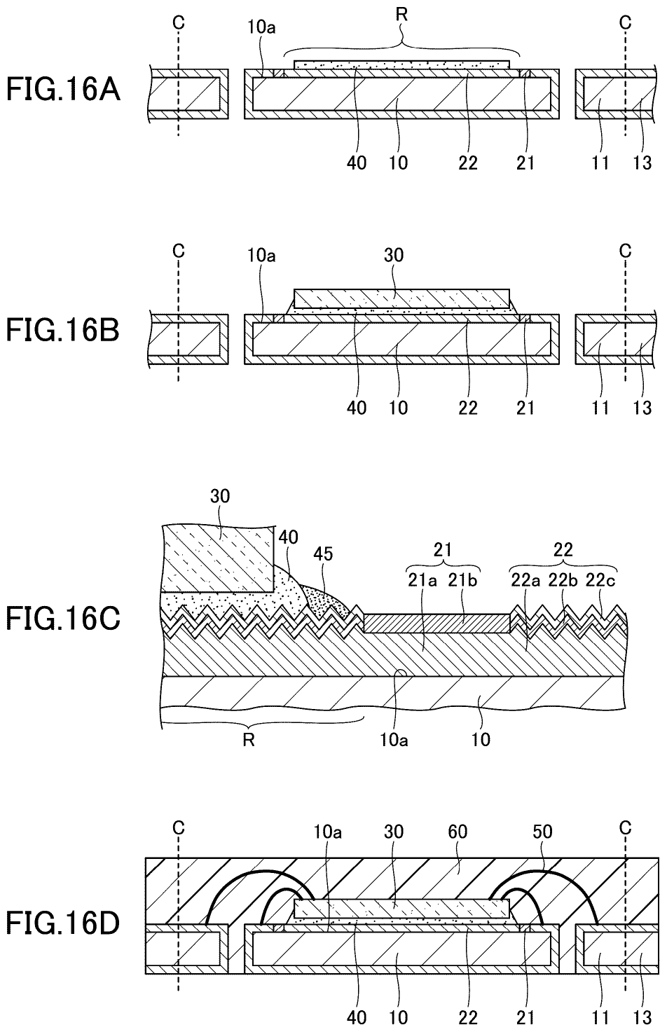

Next, a method of manufacturing the semiconductor device 2 according to the second embodiment is described. FIGS. 16A through 16D are diagrams illustrating a method of manufacturing a semiconductor device according to the second embodiment.

Referring to FIG. 16A, first, the adhesive 40 is applied to the mounting region R of the die pad 10 of each individual piece region C of the leadframe 1. Referring to FIG. 16B, next, the semiconductor chip 30 is mounted face-up on the adhesive 40, and heating is performed to cure the adhesive 40. As a result, the semiconductor chip 30 is fixed to the die pad 10. For example, an adhesive containing resin such as epoxy resin or polyimide resin is used as the adhesive 40. Conductive filler such as silver or copper may be contained in such resin. The adhesive 40 is, for example, Ag paste.

Referring to FIG. 16C, because the roughened film 22 is provided in the mounting region R, a solvent component 45 contained in the adhesive 40 wets and spreads within the mounting region R through capillary action. Outside the mounting region R, however, the flat film 21 enclosing the mounting region R is formed. Therefore, in the process illustrated in FIG. 16C, the solvent component 45 is prevented from wetting and spreading into the flat film 21, and remains within the mounting region R. Accordingly, the solvent component 45 is prevented from wetting and spreading to the outside of the mounting region R.

Referring to FIG. 16D, next, electrode terminals formed on the upper surface of the semiconductor chip 30 are electrically connected to the upper surface 10a of the die pad 10 and the upper surfaces of the leads 11 via the metal wires 50. The die pad 10 is connected to a ground terminal of the semiconductor chip 30. This makes it possible to use the die pad 10 as a ground conductor. The metal wires 50 may be connected by, for example, wire bonding. Next, the resin 60 that encapsulates the semiconductor chip 30 and the metal wires 50 is formed. For example, so-called mold resin, namely, epoxy resin containing filler, may be used as the resin 60. The resin 60 may be formed by, for example, transfer molding or compression molding. Thereafter, the structure illustrated in FIG. 16D is cut at the positions of the dashed lines (positions inside the frame 13 of the leadframe 1), so that multiple semiconductor devices 2 separated into individual pieces are completed.

All examples and conditional language provided herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

Various aspects of the subject-matter described herein may be set out non-exhaustively in the following numbered clauses:

1. A method of manufacturing a leadframe including a die pad, the method including:
forming a roughened film inside and outside a region for mounting a semiconductor chip in a plan view on a surface of the die pad by forming a roughened plating film on the surface of the die pad and stacking a plating film on the roughened plating film such that the plating film follows a shape of the roughened plating film to have a roughened surface; and
forming a flat film along an outer edge of the region, the flat film having a flatter surface than the roughened film, by irradiating a part of the roughened film positioned outside the region with laser light such that the flat film includes a first metal film formed of a same metal as the roughened plating film and a second metal film stacked on the first metal film, the second metal film being an alloy film including a metal of the roughened plating film and a metal of the plating film.

2. The method of clause 1, wherein a green laser is employed to irradiate the part of the roughened film with the laser light.

What is claimed is:

1. A leadframe comprising:
a die pad having a surface that includes a region for mounting a semiconductor chip;
a flat film on the surface of the die pad, the flat film being along an outer edge of the region outside the region in a plan view; and
a roughened film on the surface of the die pad, the roughened film being inside and outside the flat film in the plan view, the roughened film including
a roughened plating film; and
a plating film on the roughened plating film, the plating film following a shape of the roughened plating film to have a roughened surface,
wherein the flat film has a surface flatter than a surface of the roughened film, and includes
a first metal film formed of a same material as the roughened plating film; and
a second metal film on the first metal film, the second metal film being an alloy film including a metal of the roughened plating film and a metal of the plating film.

2. The leadframe as claimed in claim 1, wherein the flat film has a frame or ring shape along the outer edge of the region.

3. The leadframe as claimed in claim 1, wherein the flat film has a glossiness higher than a glossiness of the roughened film.

4. The leadframe as claimed in claim 3, wherein the glossiness of the flat film is at least twice and at most three times the glossiness of the roughened film.

5. The leadframe as claimed in claim 1, wherein
the flat film has an S ratio of 1.01 or more and 1.10 or less, and
the roughened film has an S ratio of more than 1.10 and 2.20 or less.

6. The leadframe as claimed in claim 1, wherein
the flat film has an arithmetic mean height Sa of 20 nm or more and 50 nm or less, and
the roughened film has an arithmetic mean height Sa of 80 nm or more and 120 nm or less.

7. The leadframe as claimed in claim 1, wherein
a maximum height of the flat film is smaller than a maximum height of the roughened film relative to the surface of the die pad, and
a difference between the maximum height of the flat film and the maximum height of the roughened film relative to the surface of the die pad is less than 1 μm.

8. The leadframe as claimed in claim 1, wherein
the roughened plating film is formed of copper or nickel,
the plating film includes
a first plating film formed of palladium on the roughened plating film; and
a second plating film formed of gold on the first plating film, and
the second metal film is the alloy film of copper or nickel, palladium, and gold.

9. The leadframe as claimed in claim 1, wherein
the roughened plating film is formed of copper,
the plating film includes
a first plating film formed of nickel on the roughened plating film;
a second plating film formed of palladium on the first plating film; and
a third plating film formed of gold on the second plating film, and
the second metal film is the alloy film of copper, nickel, palladium, and gold.

10. The leadframe as claimed in claim 1, wherein the surface of the flat film is a laser-irradiated surface.

11. The leadframe as claimed in claim 1, wherein the flat film has a width of 0.1 mm or more and 2 mm or less.

12. The leadframe as claimed in claim 1, wherein the flat film has a U shape, a shape of two parallel straight lines, or a shape of a single straight line in the plan view.

13. The leadframe as claimed in claim 1, wherein a surface of the first metal film facing away from the die pad is flatter than a surface of the roughened plating film facing away from the die pad.

14. A semiconductor device comprising:
the leadframe as set forth in claim 1;
a semiconductor chip mounted on the region using an adhesive; and
a resin contacting the roughened film outside the flat film and encapsulating the semiconductor chip.
